(19) United States
(12) Patent Application Publication
(10) Pub. No.: US 2024/0429178 A1
(43) Pub. Date: Dec. 26, 2024

(54) MONOLITH STRUCTURE FOR BSPDN SEMICONDUCTOR DEVICES

(71) Applicant: INTERNATIONAL BUSINESS MACHINES CORPORATION, Armonk, NY (US)

(72) Inventors: Nicholas Alexander Polomoff, Hopewell Junction, NY (US); Brent A. Anderson, Jericho, VT (US); Lawrence A. Clevenger, Saratoga Springs, NY (US); Matthew Stephen Angyal, Stormville, NY (US); Fee Li Lie, Albany, NY (US); Ruilong Xie, Niskayuna, NY (US); Terence Hook, Jericho Center, VT (US)

(21) Appl. No.: 18/211,669

(22) Filed: Jun. 20, 2023

(51) Int. Cl. H01L 23/00; H01L 23/367; H01L 23/58

(52) U.S. Cl. CPC H01L 23/562; H01L 23/3672; H01L 23/564; H01L 23/585

(57) ABSTRACT

A semiconductor device is provided. The semiconductor device includes a semiconductor device comprising: a back end of the line (BEOL) stack including a dielectric stack, and an active device region in the dielectric stack, the active device region including at least one component selected from the group consisting of transistors, capacitors and nanosheet structures; and a crack stop that extends vertically through the active device region.

### BACKGROUND

The present disclosure relates to fabrication methods and resulting structures for integrated circuit (IC) semiconductor devices, and more specifically to crack stop architectures used to restrict crack propagation during the dicing of semiconductor wafers. More specifically, the present disclosure relates to fabrication methods and resulting structures for semiconductor devices including a crack stop structure that is effective in halting crack propagation within the back end of line (BEOL) interconnect stacks. The crack stop structure may be used with semiconductor devices including a backside power distribution network (BSPDN).

In conventional semiconductor device manufacturing, economies of scale, including decreased incidences of processing errors, increased throughput, and ease of handling, may be achieved through the simultaneous processing of a large number of integrated circuit (IC) chips on the surface of a single semiconductor substrate before the substrate is cut (or diced) into individual chips. The dicing process and the associated stresses, however, may create and propagate cracks into the active device region of the chips, resulting in device failure and decreased manufacturing throughput. Moisture can also permeate the structure of the die. One technique to protect against such failures is to incorporate a physical barrier (or crack stop, or die seal, or edge seal) that surrounds the fragile, active prime area of the semiconductor device.

### SUMMARY

Embodiments of the present disclosure relate to a semiconductor device. The semiconductor device includes: a back end of the line (BEOL) stack including a dielectric stack, and an active device region in the dielectric stack, the active device region including at least one component selected from the group consisting of transistors, capacitors and nanosheet structures; and a crack stop that extends vertically through the active device region.

Embodiments of the present disclosure relate to a semiconductor device. The semiconductor device includes a back end of the line (BEOL) stack on the substrate, the BEOL stack including a first dielectric stack, an active device region on in the first dielectric stack, the active device region including at least one component selected from the group consisting of transistors, capacitors and nanosheet structures, and a second dielectric stack on the active device region; a first segmented crack stop that surrounds an active prime region of the semiconductor device and that extends vertically through the active device region; and a second monolithic continuous crack stop that surrounds the first segmented crack stop, and that extends through vertically through the active device region.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 is a perspective view of a semiconductor device including a single monolithic rail crack stop, according to embodiments.

FIG. 2 is a top-down view of a semiconductor device including a single monolithic rail crack stop, according to embodiments.

FIG. 3 is a top-down view of a semiconductor device including a double monolithic rail crack stop, according to embodiments.

FIG. 4 is a top-down view of a semiconductor device including a first single monolithic rail crack stop and a second segmented rail crack stop, according to embodiments.

FIG. 5A is partial cross-sectional view of a semiconductor device including a double monolithic rail crack stop at an intermediate stage of the fabrication process, according to embodiments.

FIG. 5B is partial cross-sectional view of the semiconductor device of FIG. 5A at a subsequent stage of the fabrication process, according to embodiments.

FIG. 5C is partial cross-sectional view of the semiconductor device of FIG. 5B at a subsequent stage of the fabrication process, according to embodiments.

FIG. 5D is partial cross-sectional view of the semiconductor device of FIG. 5C at a subsequent stage of the fabrication process, according to embodiments.

FIG. 5E is partial cross-sectional view of the semiconductor device of FIG. 5D at a subsequent stage of the fabrication process, according to embodiments.

FIG. 6 is partial cross-sectional view of a semiconductor device including a single monolithic rail crack stop, according to embodiments.

FIG. 7 is a partial cross-sectional view of a semiconductor device including a double monolithic rail crack stop that extends through the substrate to a heat sink, according to embodiments.

FIG. 8 is a partial cross-sectional view of a semiconductor device including a double monolithic rail crack stop that extends partially through the substrate, according to embodiments.

### DETAILED DESCRIPTION

Reference will now be made in greater detail to various embodiments of the subject matter of the present disclosure, some embodiments of which are illustrated in the accompanying drawings. The same reference numerals will be used throughout the drawings to refer to the same or similar parts.

Some flowcharts and cross-sectional diagrams in the Figures illustrate methods of manufacturing nanosheet FET devices according to various embodiments. In some alternative implementations, the manufacturing steps may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures that correspond to the use of those terms. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, microelectronic semiconductor IC devices such as Complementary Metal Oxide Semiconductor Field Effect Transistor (CMOS FET) devices and the like are manufactured in a complex process in which numerous separate electronic devices are formed. Such processes of manufacture, which produce large numbers of such electronic devices, are referred to as Very Large Scale Integration (VLSI) processes. After many processing steps semiconductor wafers must be subdivided by dicing to form the numerous, individual semiconductor chips.

Various processes and structures have been implemented to reduce the number of chip failures due to crack propagation during dicing. Many conventional crack stop structures, for instance, are constructed during the formation of active device regions, and hence are built up layer-by-layer. However, such designs can create fragile interfaces between multiple sub-layers of the crack stop structure as well as the potential for misalignment and unlanded structures. However, the crack stop structures according to the various embodiments described herein may allow for improved survivability of nanosheet or BSPDN based devices, and the prevention of chip packaging interaction (CPI) fails in interconnect structures formed during Back End Of Line (BEOL) interconnect fabrication.

In certain embodiments, a semiconductor device is provided that includes a crack stop (or crack arresting) structure including at least one solid monolithic structure that traverses (i.e., in the thickness direction of the semiconductor device) an active device region and multiple dielectric layers of a backside power rail, and is peripheral to (or surrounds) a central active prime region of an IC chip. In certain embodiments, the crack stop (or crack arresting structure) is positioned between the active prime region and a kerf region of the semiconductor device. As used herein, a “monolithic” structure refers to a single continuous solid structure. As used herein, a “kerf region” refers to a scribing area or a dicing channel between adjacent dies, for example, as well as a region from which material is lost during scribing or dicing. As used herein, an “active prime region” refers to a central part of the die when viewed in plan view, around which the crack stop structure is formed. The active prime region is therefore located in a generally central location of the die and inside the crack stop structure and guard rail. The active prime region comprises, for example, active and passive electrical devices, which provide the IC's functionality. The active and passive electrical devices are formed within the semiconductor layers of the active prime region, which is located inside the crack stop that separates the active region from the kerf region. The IC chip, including both the active prime region and the kerf region, is covered by a plurality of metallization layers, each of the metallization layers including a patterned intermetallic dielectric layer that includes vias and an overlaying patterned metal layer. Within the active prime region, each of the plurality of metallization layers includes electrical contacts, formed within the vias that contact the overlying patterned metal layer. The patterned metal layer forms interconnects with the electrical contacts to the underlying active and passive electrical devices of the semiconductor layer.

As used herein, an “active device region” refers to a layer or layers that includes at least one of a transistor, nanosheet structure, capacitor, memory device (or more generally an electronic structure capable of sending or receiving an electrical signal). In certain embodiments, the active device region extends horizontally across the active prime region, across a region occupied by a guard rail, and into an area occupied by the crack stops. As will be explained further herein, the crack stopping structures of the present embodiments are adapted to halt propagating cracks and prevent their entry into the active prime region, and to reduce the likelihood of delamination of one or more layers of the BEOL stack (e.g., near the active device region).

The present embodiments relate to semiconductor devices and methods for forming semiconductor devices including a BEOL stack, where an active device region (i.e., which may include devices such as transistors, capacitors, nanosheet structures, etc.) is formed in the middle of the backside stack in a thickness direction thereof (i.e., as opposed to at the bottom of the BEOL stack, near or at the substrate surface, or embedded into the substrate itself). Because the active device region is formed in the middle of the backside power distribution network (BSPDN) stack or BEOL stack, certain effects may arise that are related to crack propagation. For example, the materials of the layers/devices in the active device region may be porous which could allow for moisture penetration. Also, the materials of the layers/devices in the active device region may be mechanically weaker than the materials of other layers of the BEOL stack, and thus may be more prone to delamination because of the position of the active device region in the middle of the BEOL stack.

However, the crack stop of the present embodiments provides several features that eliminate or lessen such effects. In certain embodiments, the crack stop monolithic wall barrier can block crack propagation due to dicing (or singulation) operations. The crack stop may also prevent or reduce moisture ingress. When a semiconductor wafer is diced into individual dies, there may be nascent cracks (i.e., cracks formed from the dicing operation) that can be exacerbated over time with mechanical vibration from the operation of the semiconductor device, humidity changes, expansion and contraction due to temperature changes, and moisture ingress. One or more of these conditions has the potential to expand any nascent cracks into a larger crack that could cause delamination of certain layers and possibly impact the performance of the semiconductor device. In related devices, where the active device region is adjacent to the substrate, the rigidity and material properties of the substrate may offer some protection from issues associated with the propagation of cracks or delamination. In the present embodiments, with the active device region located in the middle of the BSPDN stack (rather than on the substrate), these layers may be more susceptible to crack propagation and the associated performance effects. However, in the present embodiments, the crack stop extends vertically through (and above and below) the active device regions, which allows for greater protection against crack propagation for this relatively fragile active device region. In other words, the crack stop bridges through the active device region. In certain embodiments, the crack stop is not electrically connected to any other portion of the semiconductor device.

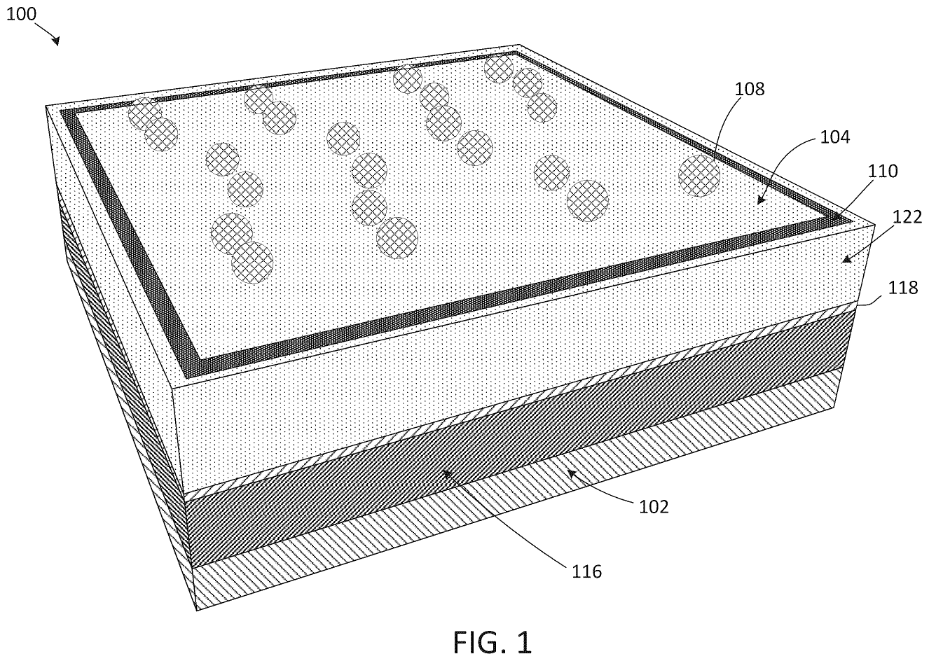

Referring now to the drawings in which like numerals represent the same or similar elements and initially to FIG. 1, this figure depicts a schematic perspective view of a semiconductor device 100, according to embodiments. As shown in FIG. 1, a substrate 102 is provided. The substrate 102 may be a bulk-semiconductor substrate, and may function as a carrier substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor-on-insulator (SOI) substrate. The substrate 102 may be comprised of any other suitable material(s) that those listed above. In some embodiments, the substrate 102 includes both semiconductor materials and dielectric materials.

As shown in FIG. 1, a multiple layer BEOL structure is formed on top of the substrate 102. In certain embodiments, the BEOL structure includes a frontside dielectric stack 116 formed on the carrier substrate 102, an active device region 118 formed on the frontside dielectric stack 116, and a backside dielectric stack 122 formed on the active device region 118. It should be appreciated that the frontside dielectric stack 116 and the backside dielectric stack 122 may each include a plurality of different dielectric layers. Moreover, the active device region 118 may include a plurality of different active device regions, and there may be a plurality of different active device regions 118 separated by one or more dielectric layers. In certain embodiments, the active device region 118 may extend horizontally across the die from the kerf region to the active prime region 104.

As also shown in FIG. 1, a crack stop 110 is formed as a seamless monolithic structure that surrounds an active prime region 104 of the semiconductor device 100. In certain embodiments, the crack stop 110 extends vertically through the active device region 118. The crack stop 110 may comprise one or more of copper, aluminum, tungsten, 2-(trimethylsilyl)ethoxycarbonyl (TEOC), and/or a mechanically strong dielectric material. Solder balls 108 are generically shown in the active prime region 104, and it should be appreciated that any suitable number or arrangement of solder balls 108 may be used. The solder balls 108 may serve as electrical contacts for the BSPDN. It should be appreciated that certain elements of the semiconductor device 100 are not shown in FIG. 1 for the sake of simplicity and ease of illustration, and FIG. 1 is intended to show the position of the crack stop 110 relative to other major components of the semiconductor device 100.

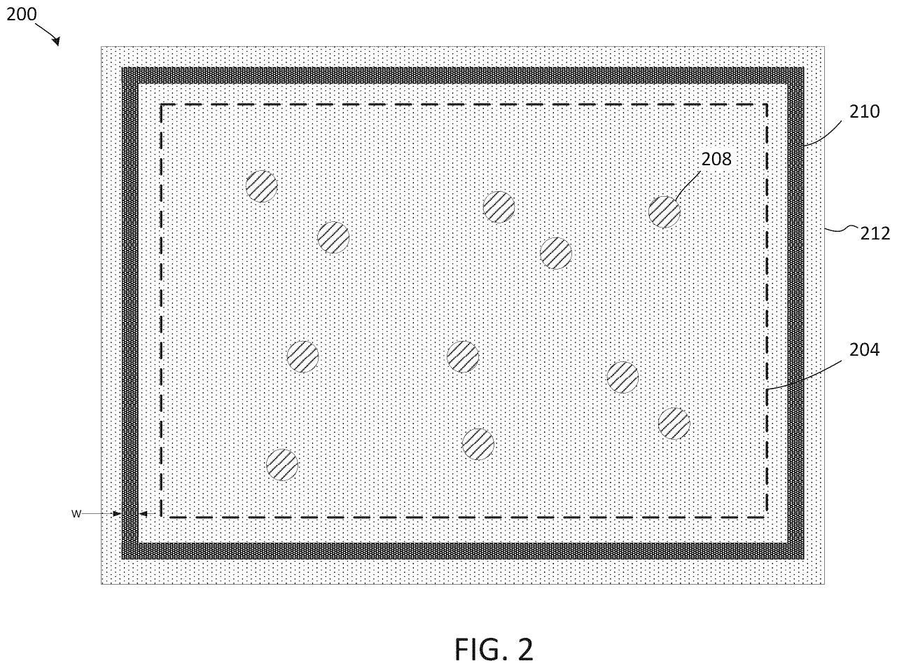

Referring now to FIG. 2, this figure shows a top-down view of a semiconductor device 200 including a single monolithic rail crack stop, according to embodiments. Similar to the description of FIG. 1 above, the semiconductor device 200 includes a substrate. A crack stop 210 is formed as a solid monolithic wall that surrounds the active prime region 204 of the semiconductor device 200. The crack stop 210 may comprise one or more of copper, aluminum, tungsten, 2-(trimethylsilyl)ethoxycarbonyl (TEOC), and/or a mechanically strong dielectric material. An example arrangement of solder balls 208 is also shown in the active prime region 204. In certain embodiments, walls of the crack stop 210 have a width (W) of about 3-6 μm. However, it should be appreciated that the width of the crack stop structure may be any suitable width. In certain embodiments the crack stop 210 is not electrically connected to other active portions of the semiconductor device 200.

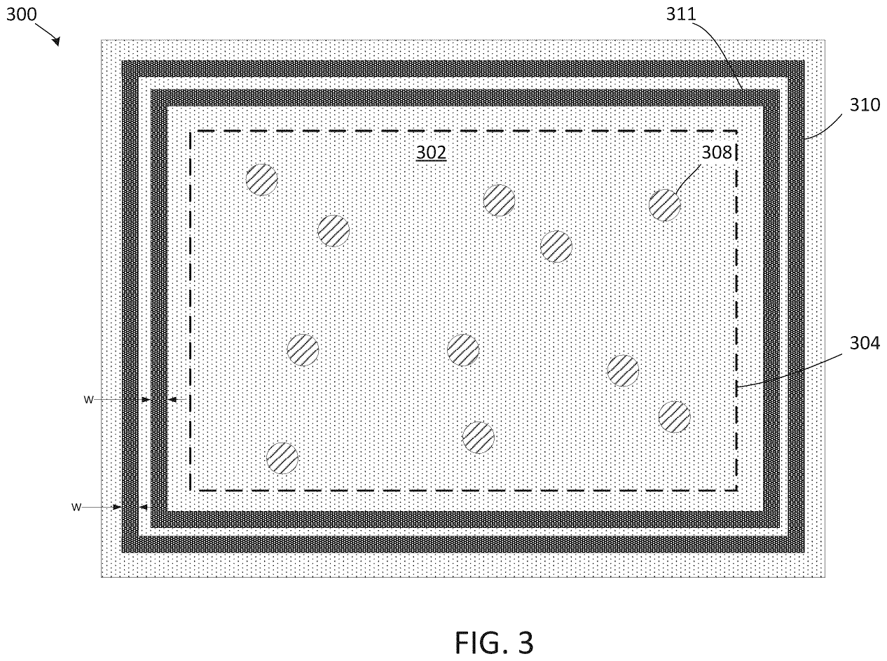

Referring now to FIG. 3, this figure shows a top-down view of a semiconductor device 300 including a double monolithic rail crack stop, according to embodiments. Similar to the description of FIG. 1 above, the semiconductor device 300 includes a substrate 302. A crack stop structure includes a first crack stop 310 and a second crack stop 311 that are formed as solid monolithic walls that surrounds the active prime region 304 of the semiconductor device 300. As shown in FIG. 3, the first crack stop 310 surrounds the second crack stop 311, and there is a separation between the first crack stop 310 and the second crack stop 311. The crack stop structures may comprise, for example, one or more of copper, aluminum, tungsten, 2-(trimethylsilyl)ethoxycarbonyl (TEOC), and/or a mechanically strong dielectric material. An example arrangement of solder balls 308 is also shown in the active prime region 304. In certain embodiments, walls of the first crack stop 310 and the second crack stop 311 have a width (W) of about 3-6 μm. However, it should be appreciated that the width of the crack stop structure may be any suitable width, and the width of the first crack stop 310 may be different than the width of the second crack stop 311. In certain embodiments the first crack stop 310 and the second crack stop 311 are not electrically connected to other active portions of the semiconductor device 300. In certain embodiments, the second crack stop 311 may provide additional protection against moisture ingress and delamination and other effects related to crack propagation relative to the single wall structure shown in FIG. 2.

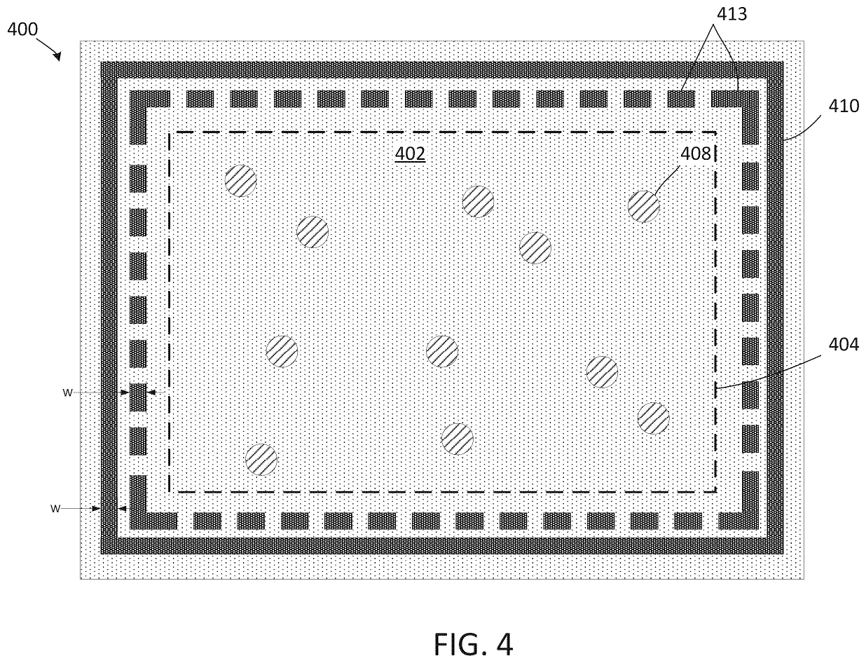

Referring now to FIG. 4, this figure shows a top-down view of a semiconductor device including a first crack stop 410 that is a single monolithic rail, and a second segmented crack stop 413 that is formed as a segmented rail, according to embodiments. Similar to the description of FIG. 1 above, the semiconductor device 400 includes a substrate 402. The crack stop structure includes the first crack stop 410 that is formed as a solid monolithic wall that surrounds the active prime region 404 of the semiconductor device 400. The crack stop structure also includes the second crack stop 413 that is a segmented (or discontinuous) structure. As shown in FIG. 2C, the first crack stop 410 surrounds the second segmented crack stop 413, and there is a separation between the first crack stop 410 and the second segmented crack stop 413. The crack stop structures may comprise, for example, one or more of copper, aluminum, tungsten, 2-(trimethylsilyl)ethoxycarbonyl (TEOC), and/or a mechanically strong dielectric material. An example arrangement of solder balls 408 is also shown in the active prime region 404. In certain embodiments, walls of the first crack stop 410 and the second segmented crack stop 413 have a width (W) of about 3-6 μm. However, it should be appreciated that the width of the crack stop structure may be any suitable width. In certain embodiments the first crack stop 410 and the second segmented crack stop 413 are not electrically connected to other active portions of the semiconductor device 400. In certain embodiments, the second crack stop 411 may provide additional protection against moisture ingress and delamination and other effects related to crack propagation relative to the single wall structure shown in FIG. 2, but may require less material than the second crack stop 411 shown in FIG. 4.

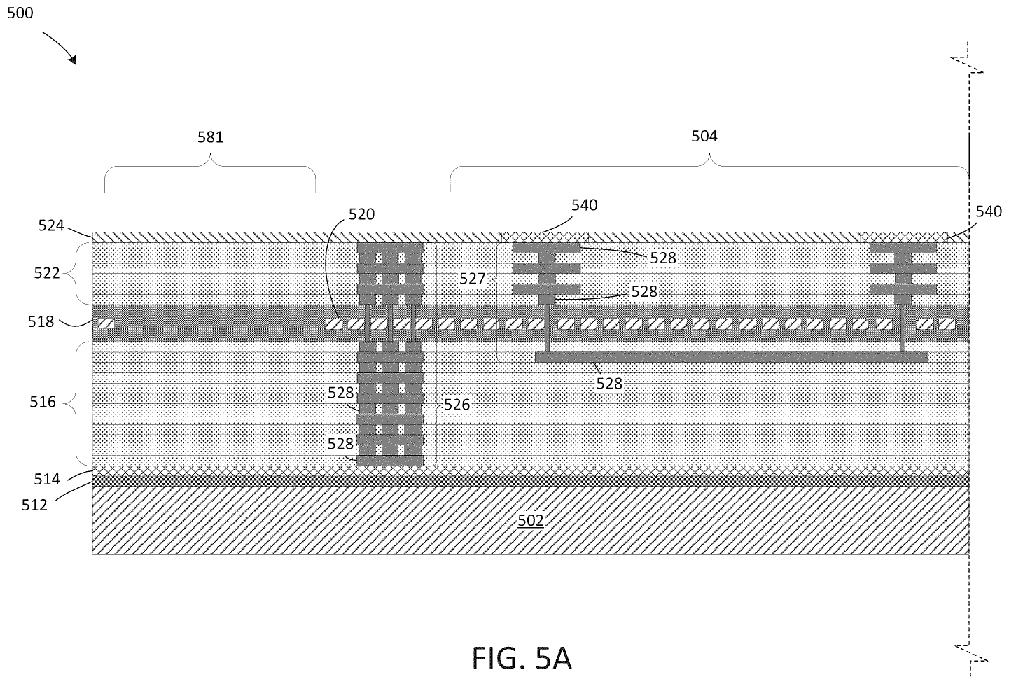

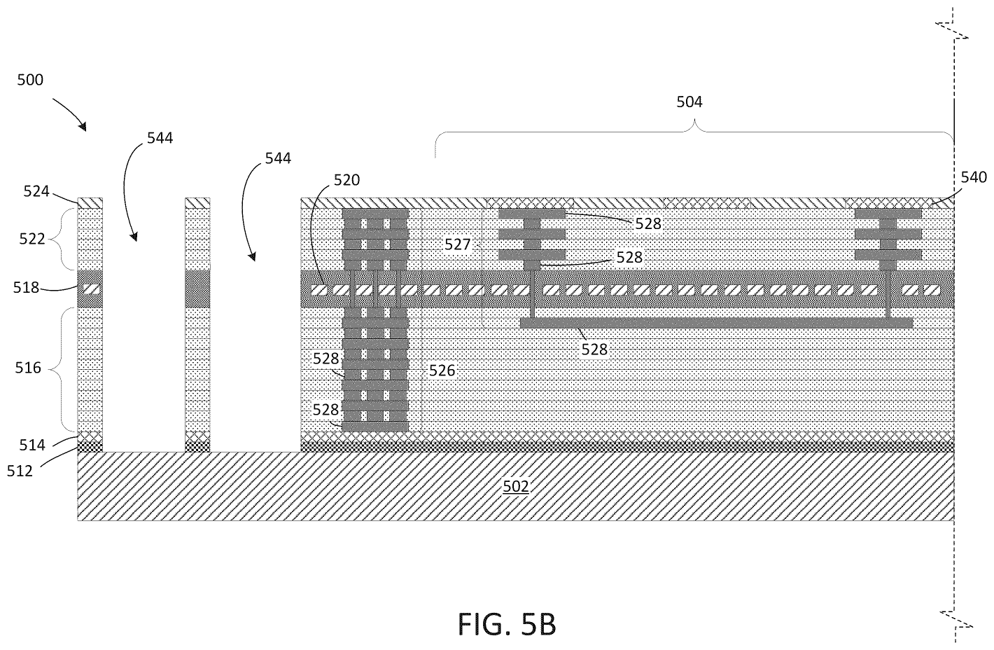

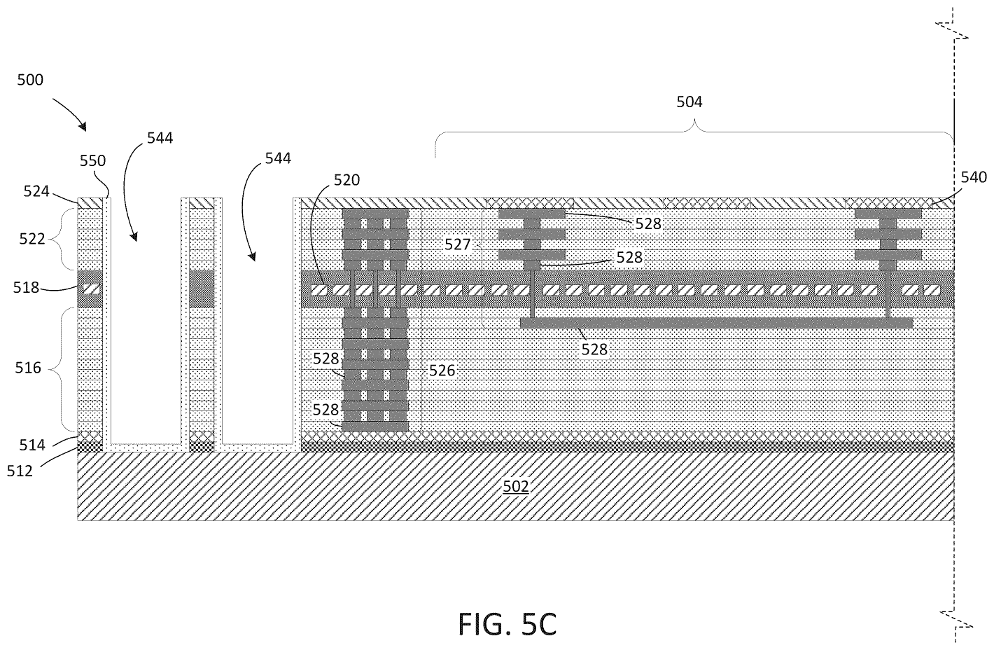

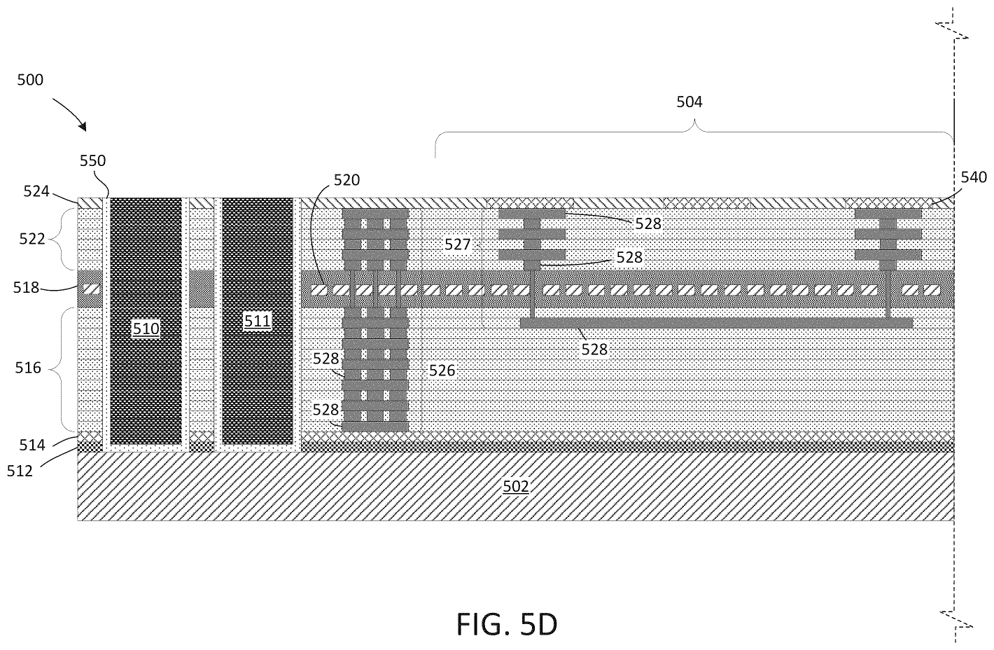

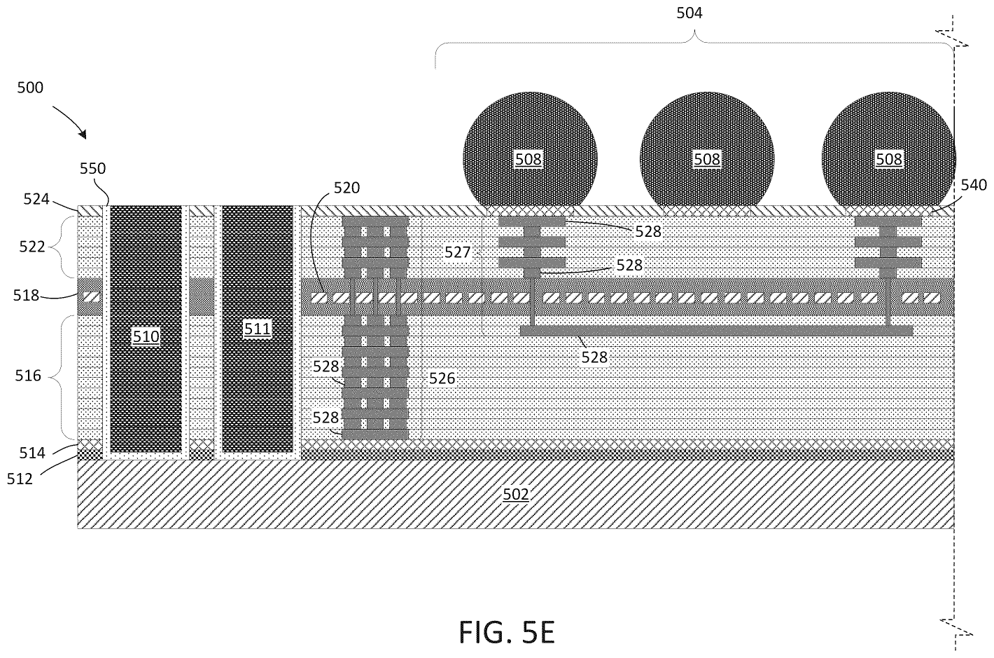

Referring now to FIGS. 5A-5E and initially to FIG. 5A, this figure shows a partial cross-sectional view (indicated by the dashed cut line on the right side of the device) of a semiconductor device 500 including a double monolithic rail crack stop structure at an intermediate stage of the fabrication process, according to embodiments. As shown in FIG. 5A, a substrate 502 is provided. The substrate 502 may be a bulk-semiconductor substrate, and may function as a carrier substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 502 may also be a semiconductor-on-insulator (SOI) substrate. The substrate 502 may be comprised of any other suitable material(s) that those listed above. In some embodiments, the substrate 502 includes both semiconductor materials and dielectric materials.

As also shown in FIG. 5A, in certain embodiments, an adhesive layer 512 is formed on the substrate 502. The adhesive layer 512 may include any suitable adhesive material or combination of materials. A capping layer 514 is formed on the adhesive layer 512. In certain examples, the capping layer comprises a hard mask material such as N-BLOK. A frontside dielectric stack 516 is formed on the capping layer 514. It should be appreciated that the frontside dielectric stack 516 may include more or less layers than are shown in FIG. 5A, and the layers are not necessarily shown drawn to scale (i.e., certain of the dielectric layers may be of different thicknesses than others). An active device region 518 is formed on the frontside dielectric stack 516. The active device region 518 may include a plurality of devices 520 such as transistors, capacitors, nanosheet structures, etc., and may include one or more dielectric layers. It should be appreciated that the devices 520 are shown generically in FIG. 5A, and any suitable number of devices 520, arrangement of devices 520, and combination of different types of devices 520 may be contemplated in the present embodiments. It should also be appreciated that although only one active device region 518 is shown in FIG. 5A, two or more active device regions may be present at different heights in the BEOL stack structure, and the crack stops may extend through a plurality of these different active device regions. The concept of multiple active device regions may apply to any of the embodiments described herein.

As also shown in FIG. 5A, a backside dielectric stack 522 is formed on the active device region 518. It should be appreciated that the backside dielectric stack 522 may include more or fewer layers than are shown in FIG. 5A, and the layers are not necessarily shown drawn to scale (i.e., certain of the dielectric layers may be of different thicknesses than others). As mentioned above, the active device region 518 may be a structurally weaker layer relative to the frontside dielectric stack 514 and the backside dielectric stack 522, and has the potential to result in delamination (or peeling) due to cracks formed in the semiconductor device during a dicing operation. As shown in FIG. 5A, a top layer 524 may be formed on the backside dielectric stack. The top layer 524 may comprise a polymer such as a polyimide, SiN, aluminum, or other suitable materials. In certain embodiments, the frontside dielectric stack 516, the active device region 518, and the backside dielectric stack 522 are elements of a back end of line (BEOL) stack of a backside power distribution network (BSPDN).

To give additional context regarding the position of the crack stop (see, crack stop 510 in FIG. 5D) relative to the active prime region 504 of the semiconductor device 500, several additional components of the semiconductor device 500 are shown. For example, a guard ring 526 may be formed that traverses the backside dielectric stack 522, the active device region 518 and the frontside dielectric stack 516. In general, a guard ring 526 is a structure that, unlike the crack stop, is electrically connected to other components of the semiconductor device 500, and creates electrical isolation around the active prime region 504. The guard ring 526 typically includes a stack of back-end-of-line (BEOL) metal interconnect structures 528 that are located on an outer periphery of a semiconductor chip. The guard ring 526 may also function as a metal seal against ionic contaminants. The guard ring 526 may also function as a low resistance path between electrical ground nodes of semiconductor devices on the semiconductor substrate 502 and grounding metal pads (not shown) located on the top surface of dielectric layers including back-end-of-line metal interconnect structures of the semiconductor chip. In certain examples, the guard ring 526 creates a Faraday cage so that any neighboring chips that are assembled near to the semiconductor device 500 do not interfere with the active prime area 504. It should be appreciated that the guard ring 526 is shown in a generic manner for ease in understanding the location of same relative to the crack stops, and the guard ring 526 may include any suitable number of layers other than that shown in FIG. 5A. In certain embodiments, the active prime region 504 may be considered to be the area inside of the guard ring 526, as shown in FIG. 5A. However, in certain embodiments, the active prime region 504 may be considered to include both the area inside of the crack stop structures and the area occupied by the guard ring 526, as seen in plan view.

As also shown in FIG. 5A, one or more backside power metallic interconnects 527 including one or more BEOL metal interconnect structures 528 may be present in the active prime area 504. Similar to the guard ring 526, it should be appreciated that the backside power metallic interconnect 527 is shown in a generic manner for ease of understanding, and to show the location of the backside power metallic interconnect 527 relative to the crack stops. The backside power metallic interconnect 527 may include any suitable number of layers other than that shown in FIG. 5A. In other words, the guard ring 526 and the backside power metallic interconnect 527 are depicted in the figures simply to show certain structures that may commonly be included in the semiconductor device 500, and to show where the crack stops are positioned relative to same. A crack stop area 581 is also shown in FIG. 5A, and this is an area outside the active prime region 504 of the semiconductor device 500. As also shown in FIG. 5A, metal contacts 540 are formed on the backside power metallic interconnects 527.

Referring now to FIG. 5B, this figure is partial cross-sectional view of the semiconductor device of FIG. 5A at a subsequent stage of the fabrication process and including a double monolithic rail crack stop, according to embodiments. As shown in FIG. 5B, a suitable material removal process, such as reactive ion etching (RIE) is performed on the semiconductor device 500. The RIE process etches through the top layer 524, the backside dielectric stack 522, the active device region 518, the frontside dielectric stack 516, the capping layer 514 and the adhesive layer 512 to expose the substrate 502. Although not shown in FIG. 5B, a patterned etching mask may be formed on the top layer 524 to allow for etching of the crack stop recesses 544.

Referring now to FIG. 5C, this figure is a partial cross-sectional view of the semiconductor device of FIG. 5B at a subsequent stage of the fabrication process, according to embodiments. As shown in FIG. 5C a liner layer 550 is conformally deposited in the crack stop recesses 544 with any suitable material deposition technique, such as sputtering. Thus, the liner layer 550 is formed on the substrate 502 and on the sidewalls of the top layer 524, the backside dielectric stack 522, the active device region 518, the frontside dielectric stack 516, the capping layer 514 and the adhesive layer 512. The liner layer 550 may comprise TaN or any other suitable liner layer material. Although not shown in FIG. 5C, the liner layer 550 may include a seed layer made of, for example, TaN, TiW, CuMn, etc.

Referring now to FIG. 5D, this figure is partial cross-sectional view of the semiconductor device 500 of FIG. 5C at a subsequent stage of the fabrication process, according to embodiments. As shown in FIG. 5D, a suitable material deposition process is performed to fill the crack stop recesses 544 with material to form the crack stops 510. Thus, the crack stop structure of FIG. 5D includes a first crack stop 510 and a second crack stop 511 that are formed as solid monolithic walls that surrounds the active prime region 504 of the semiconductor device 500 (see also FIG. 5B). As shown in FIG. 5D, the first crack stop 510 surrounds the second crack stop 511, and there is a separation between the first crack stop 510 and the second crack stop 511. The crack stop structures may comprise, for example, one or more of copper, aluminum, tungsten, 2-(trimethylsilyl)ethoxycarbonyl (TEOC), and/or a mechanically strong dielectric material. As also shown in FIG. 5D, the first crack stop 510 and the second crack stop 511 extend through the backside dielectric stack 522, the active device region 518 and the frontside dielectric stack 516 down to the substrate 502. After the formation of the first crack stop 510 and second crack stop 511, an optional CMP process may be used to remove any excess material of the crack stops and planarize the semiconductor device 500. A top surface of the crack stops can correspond to the top layer 524. In certain embodiments, the bottom surface of the crack stops can terminate in one of the dielectric layers of the frontside dielectric stack 516 rather than terminating directly on (or into) the substrate 502. It should be appreciated that in certain embodiments, the first crack stop 510 and the second crack stop 511 include only the crack stop structures. In other embodiments, the first crack stop 510 and the second crack stop 511 include any seed layer (not shown), the liner layer 550 and the material of the crack stop structures that fills the crack stop recesses 544. Thus, in these embodiments, the crack stops as a whole are considered to directly contact the underlying layer (e.g., the substrate or a heat sink). This concept of direct contact to the underlying portion of the dielectric stack 522, the substrate 502 or the heat sink may apply to any of the embodiments described herein. Also, in other embodiments, the seed layer and the liner layer 550 may be omitted.

Referring now to FIG. 5E, this figure is partial cross-sectional view of the semiconductor device of FIG. 5D at a subsequent stage of the fabrication process, according to embodiments. As shown in FIG. 5E, solder bumps 508 are formed on the metal contacts 540 in the active prime region 504, and certain of the solder bumps 508 are electrically connected to the backside power metallic interconnect 527.

Thus, in contrast to a crack stop that is formed of a plurality of different metal layers (i.e., layers corresponding to the layers of the dielectric stacks) stitched together and which may allow for delamination (or unzipping) of the crack stop itself, the single monolithic crack stops of the present embodiments are not susceptible to delamination. Moreover, in the present embodiments, the monolithic crack stops extend vertically through (and above and below) the active device region 518, which allows for greater protection against crack propagation for this relatively fragile region. In other words, the crack stop bridges through the active device region 518 to protect that portion of the BSPDN from delamination and other performance issues related to crack propagation.

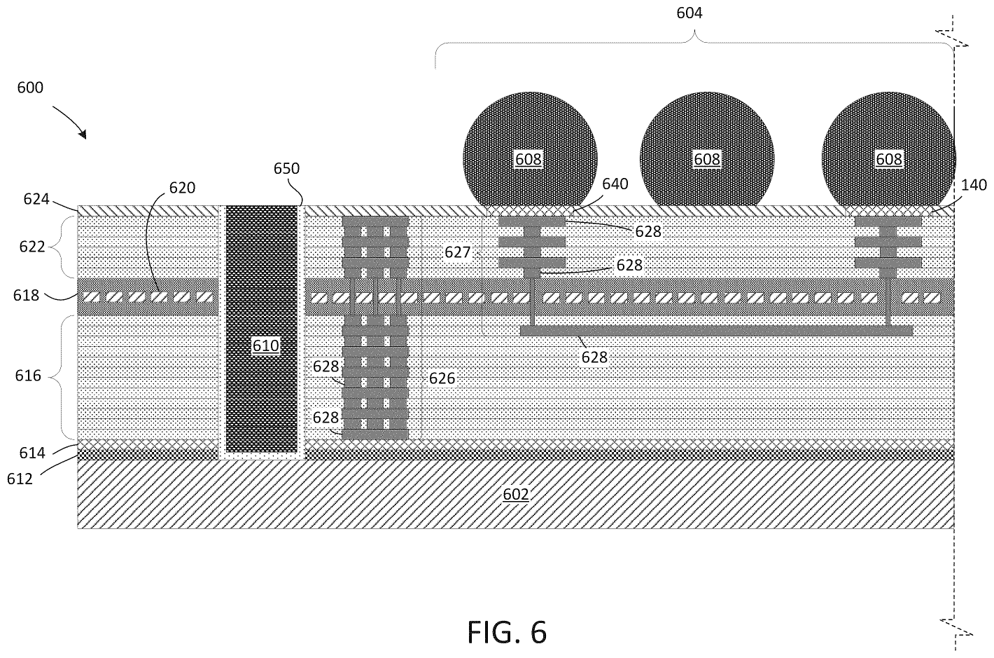

Referring now to FIG. 6, this figure is a partial cross-sectional view of a semiconductor device including a single monolithic rail crack stop 610, according to embodiments. Other than the single crack stop (i.e., versus the double rail configuration shown in FIGS. 5A-5E), the layers and the manufacturing steps may be the same as in FIGS. 5A-5E, and are not repeated here for the sake of brevity. It should be appreciated that the single crack stop 610 embodiment shown in FIG. 6 may be used in a case where the size of the semiconductor device 600 is smaller, and where there may be a smaller area in the footprint of the device to accommodate two separate crack stops. Likewise, with a larger sized die, a dual crack stop structure like that shown in FIGS. 5A-5E may be used.

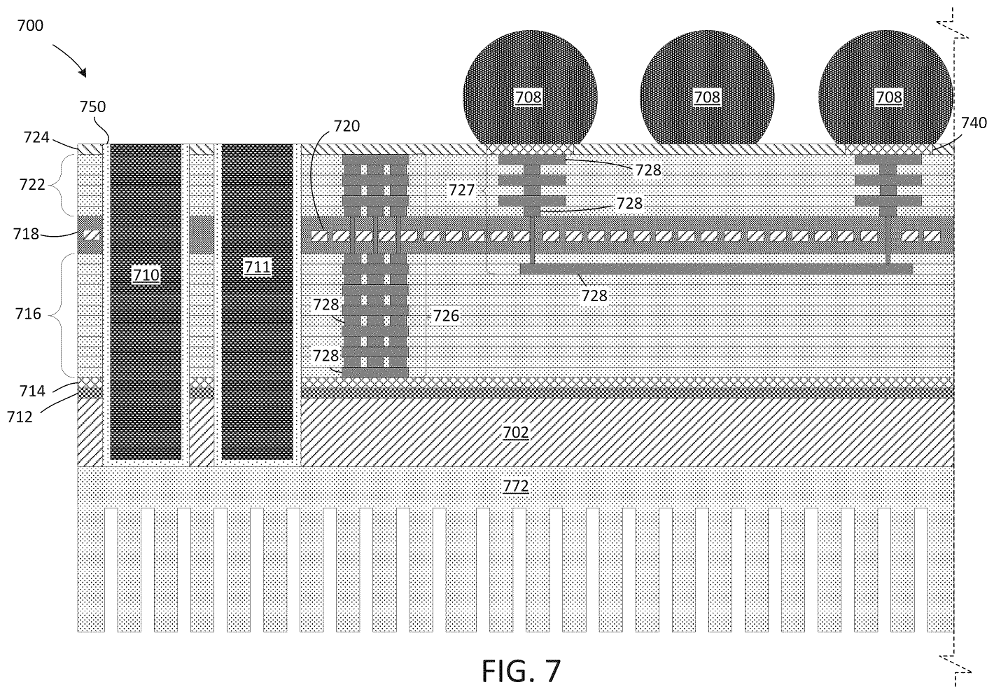

Referring now to FIG. 7, this figure is a partial cross-sectional view of a semiconductor device 700 including a double monolithic rail crack stop that extends through the substrate 702 to a heat sink 772, according to embodiments. In this embodiment, the first crack stop 710 and the second crack stop 711 extend completely through the substrate 702 to make contact with the heat sink 772. In other embodiments, the first crack stop 710 and the second crack stop 711 extend partially through the substrate 702 to be in close proximity with the heat sink 772. This may allow for heat to transfer from one or more components of the semiconductor device 700, through the cracks stops and to the heat sink 772.

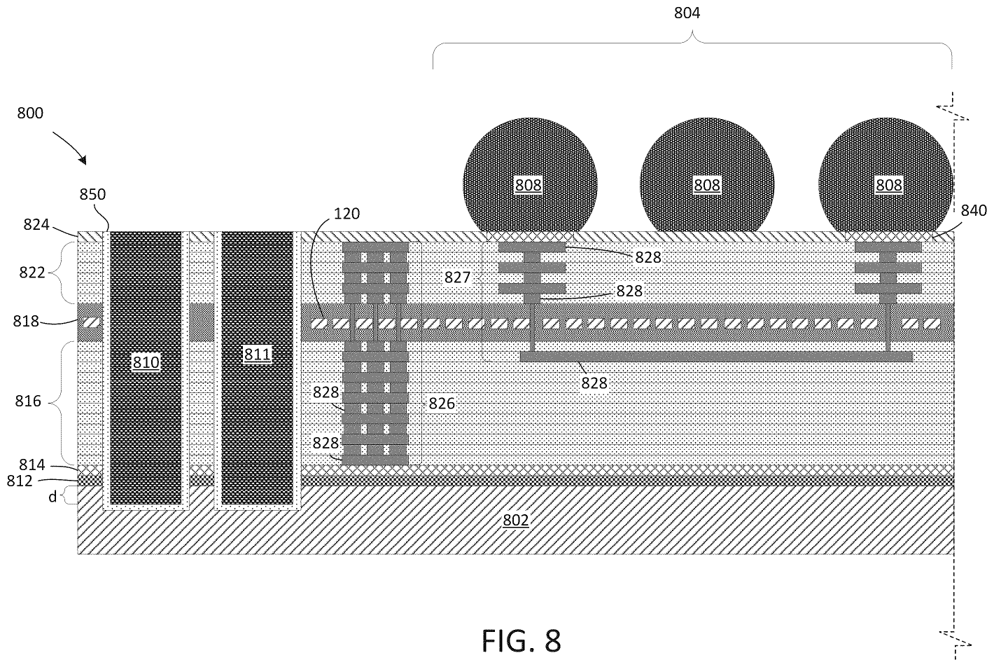

Referring now to FIG. 8, this figure is a partial cross-sectional view of a semiconductor device 800 including a double monolithic rail crack stop including a first crack stop 810 and a second crack stop 811. In this embodiment, the first crack stop 810 and the second crack stop 811 extend partially through the substrate 802, according to embodiments. As mentioned above, the active device region 818 can be susceptible to delamination. Similarly, an area near the bottom of the frontside dielectric stack 816 near the capping layer 814 and the adhesive layer 812 may also be a location that is susceptible to delamination or other damage caused by crack propagation. By etching at least partially through the substrate 802 a distance (d) and forming the first crack stop 810 and the second crack stop 811 down to that level, it has an effect of further anchoring the crack stops 810 to the substrate 802, and this may lessen the possibility of delamination in the areas adjacent to the substrate 802. In this regard, the anchoring of the first crack stop 810 and the second crack stop 811 into the substrate 802 may lessen the probability of bending, twisting, and ultimately delaminating one or more layers of the semiconductor device 800. It should be appreciated that the concept of forming the crack stop partially into the substrate 802 may apply to any of the embodiments described herein.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a back end of line (BEOL) stack including
a dielectric stack, and
an active device region in the dielectric stack, the active device region including at least one component selected from the group consisting of transistors, capacitors and nanosheet structures; and
a crack stop that extends vertically through the active device region.

2. The semiconductor device of claim 1, wherein the crack stop also extends vertically through a first portion of the dielectric stack above the active device region.

3. The semiconductor device according to claim 2, wherein the crack stop also extends through a second portion of the dielectric stack below the active device region.

4. The semiconductor device of claim 2, further comprising a substrate, the BEOL stack provided on the substrate, wherein the crack stop extends entirely though the dielectric stack and through at least a portion of the substrate.

5. The semiconductor device of claim 1, further comprising a second crack stop that surrounds the first crack stop.

6. The semiconductor device according to claim 1, wherein the crack stop comprises at least one material selected from the group consisting of copper, aluminum, tungsten, 2-(trimethylsilyl)ethoxycarbonyl (TEOC), and a dielectric material.

7. The semiconductor device according to claim 1, wherein the crack stop includes a liner layer.

8. The semiconductor device according to claim 1, further comprising:
a substrate; and
a heat sink on a bottom side of the substrate,
wherein the crack stop extends entirely though the dielectric stack and the substrate to contact the heat sink.

9. The semiconductor device according to claim 1, further comprising an active prime region, wherein the crack stop surrounds the active prime region.

10. The semiconductor device according to claim 1, further comprising a guard rail formed between the crack stop and the active prime region.

11. A semiconductor device comprising:
a back end of line (BEOL) stack including
a dielectric stack,
an active device region in the dielectric stack, the active device region including at least one component selected from the group consisting of transistors, capacitors and nanosheet structures;
a first segmented crack stop that surrounds an active prime region of the semiconductor device and that extends vertically through the active device region; and
a second continuous crack stop that surrounds the first segmented crack stop, and that extends through vertically through the active device region.

12. The semiconductor device of claim 11, wherein the first segmented crack stop and the second continuous crack stop also extend vertically through a first portion of the dielectric stack above the active device region.

13. The semiconductor device according to claim 12, wherein the first segmented crack stop and the second monolithic crack stop also extend through a second portion of the dielectric stack below the active device region.

14. The semiconductor device of claim 12, further comprising a substrate, the BEOL stack provided on the substrate, wherein the first segmented crack stop and the second monolithic crack stop extend entirely though the dielectric stack and through at least a portion of the substrate.

15. The semiconductor device of claim 11, wherein the active device region extends horizontally from a region including the crack stop and into the active prime region.

16. The semiconductor device according to claim 11, wherein the first segmented crack stop and the second monolithic crack stop each comprise at least one material selected from the group consisting of copper, aluminum, tungsten, 2-(trimethylsilyl)ethoxycarbonyl (TEOC), and a dielectric material.

17. The semiconductor device according to claim 11, wherein the first segmented crack stop and the second monolithic crack stop each include a liner layer.

18. The semiconductor device according to claim 11, further comprising:
a substrate; and
a heat sink on a bottom side of the substrate,
wherein the first segmented crack stop and the second monolithic crack stop each extends entirely though the first dielectric stack and the substrate to contact the heat sink.

19. The semiconductor device according to claim 11, further comprising a plurality of active device regions in the dielectric stack.

20. The semiconductor device according to claim 11, further comprising a guard rail formed between the first segmented crack stop and the active prime region.
